(19) United States
(12) Patent Application Publication
(10) Pub. No.: US 2012/0292688 A1
(43) Pub. Date: Nov. 22, 2012

(54) HIGHLY INTEGRATED MOS DEVICE AND THE MANUFACTURING METHOD THEREOF

(76) Inventor: Euipil Kwon, San Jose, CA (US)

(21) Appl. No.: 13/471,700

(22) Filed: May 15, 2012

(30) Foreign Application Priority Data
May 17, 2011 (KR) 10-2011-0046327

(51) Int. Cl. H01L 27/088; H01L 21/283

(52) U.S. Cl. 257/329; 438/589; 257/E21.19; 257/E27.06

(57) ABSTRACT

A MOS semiconductor device and the manufacturing method thereof relates to a highly integrated MOS device having a three-dimensional structure. The method of manufacturing the highly integrated MOS device compromises the steps of forming a layer of gate insulator on the semiconductor substrate, planarizing surface after filling a trench with an insulating material, forming a plurality of MOS transistors on the horizontal planes of a semiconductor substrate, forming vertical planes from the semiconductor substrate, and forming a plurality of MOS transistors on the vertical planes.

### CROSS REFERENCES

Applicant claims foreign priority under Paris Convention to Korean Patent Application No. 10-2011-0046327 filed May 17, 2011, with the Korean Intellectual Property Office, where the entire contents are incorporated herein by reference.

### BACKGROUND OF THE INVENTION

The present invention relates to a MOS semiconductor device and the manufacturing method thereof. More particularly, the present invention relates to a highly integrated MOS device having a three-dimensional structure.

The integrated circuits have generally been used in electronic devices for computers, communication, cars, aircraft, entertainment and other applications. They have been continually improved and thrived in terms of cost, speed, power consumption and etc. The majority of present day integrated circuits are implemented by using a plurality of interconnected metal oxide semiconductor field effect transistors (MOSFETs), or simply MOS transistors.

An MOS transistor includes a gate electrode as a control electrode, source and drain electrodes separately located at the sides of the gate electrode. A control voltage applied to gate electrode controls the flow of current through a channel between the source and drain electrodes.

The MOS transistor is fabricated on a semiconductor substrate through semiconductor process flow, and is being scaled down to increase integration density and to improve performance by using an advanced process technology.

Also, the prior art for integrating the MOS transistors is to fabricate a plurality of MOS transistors on a horizontal plane of a semiconductor substrate. Namely, a space for forming the MOS transistors is basically limited by one plane such as a horizontal plane of a semiconductor substrate.

Therefore, a new MOS device with higher space utilization to achieve higher integration density is necessary.

### SUMMARY OF THE INVENTION

The present invention provides a highly integrated MOS device forming a plurality of MOS transistors in horizontal planes of a semiconductor substrate, and further forming a plurality of MOS transistors in new vertical planes which are additionally formed in the semiconductor substrate in order to solve the problems described above.

Also, this present invention provides a method of manufacturing the highly integrated MOS device to be able to achieve high density integration of MOS transistors through creation of new dimensional space.

A method of manufacturing the highly integrated MOS device according to the present invention comprises the steps of: (1) forming a gate insulator layer on a semiconductor substrate; (2) forming trenches for isolation by etching on a surface of the semiconductor substrate; (3) planarizing the trenches in the semiconductor substrate after filling the trenches with an insulating material; (4) forming a plurality of MOS transistors on the horizontal planes of the semiconductor substrate; (5) forming vertical planes and a bottom horizontal plane by etching the semiconductor substrate; (6) forming a plurality of MOS transistors on the vertical planes;

In the MOS transistors formed at the step (4) and the step (6), one portion of the horizontal planes and the vertical planes is doped with P-type impurity dopants, another portion is doped with N-type impurity dopants.

The MOS transistors formed at the step (4) and the step (6) comprise having a combined source region and drain region, or an individual source region and drain region, and having a common gate electrode or an individual gate electrode.

The MOS transistors formed at the step (4) and the step (6) can be formed as N-channel MOS transistors, or P-channel MOS transistors in the horizontal planes and in the vertical planes.

Also, the MOS transistors formed at the step (4) and the step (6) can be formed as N-channel transistor and P-channel transistors in the horizontal planes and in the vertical planes.

The MOS transistors formed at the step (4) further comprise the step of patterning a polycrystalline silicon by photolithography and etching to form gate electrodes of N-channel MOS transistors on active regions, or gate electrodes of P-channel MOS transistors on other active regions.

The MOS transistors at the step (6) further comprise the steps of filling a trench for forming vertical planes with an insulating layer until reaching the height of a bottom boarder of transistor channel on the vertical planes, in turn, depositing a polycrystalline silicon in order to prepare a gate layer on the vertical planes.

The present invention wherein a highly integrated MOS device comprises a horizontal plane formed horizontally in a semiconductor substrate, a plurality of vertical planes formed vertically in the semiconductor substrate, and a plurality of MOS transistors on the vertical planes.

The invention comprises one portion of the horizontal planes and the vertical planes doped with P-type impurity dopants (a P-well), and another portion doped with N-type impurity dopants (an N-well), N-channel transistors on the vertical planes, or P-channel transistors on the vertical planes.

According to the present invention, the invention can increase integration density by integrating a plurality of MOS transistors on the horizontal planes as well as on the vertical planes which are newly formed.

Also, the invention has advantages in effective power interconnection and high speed operation, because the length of interconnection for electrical connections between MOS transistors is relatively reduced by highly integrating MOS transistors on three-dimensional spaces which are created unlike prior art, thus resistance and parasitic capacitance of interconnection become reduced.

### BRIEF DESCRIPTION OF THE DRAWINGS

FIG. 1 is a cross-sectional view showing preparation for manufacturing a highly integrated MOS device in accordance with the present invention.

FIG. 2 is a cross-sectional view of left and right vertical planes, a bottom horizontal plane in order to manufacture a highly integrated MOS device in accordance with the present invention.

FIG. 3 is a schematically plain view showing that a portion of a highly integrated MOS device has active regions in accordance with the present invention.

FIG. 4 is a schematically side view showing that active regions are formed on the left and right vertical planes in order to manufacture highly integrated MOS device in accordance with the present invention.

FIG. 5 is a cross-sectional view showing that a layer of gate insulating is formed on the surface of active regions and a semiconductor substrate in order to manufacture a highly integrated MOS device in accordance with the present invention.

FIG. 6 is a cross-sectional view showing patterning a polycrystalline silicon by photolithography and etching in order to form N-channel and P-channel gate electrodes in accordance with the present invention.

FIG. 7 is a cross-sectional view showing that gate sidewall spacers are formed at the gate electrodes in order to manufacture a highly integrated MOS device in accordance with the present invention.

FIG. 8 is a cross-section view showing that a polycrystalline silicon is deposited, after an insulating layer filled reaches the height of a bottom boarder of transistor channel on the vertical planes in order to manufacture a highly integrated MOS device in accordance with the present invention.

FIG. 9 is a cross-section view showing patterning a polycrystalline silicon by photolithography and etching in order to form gate electrodes on the active regions of vertical planes in accordance with the present invention.

### DETAILED DESCRIPTION OF THE INVENTION

The following detailed description is merely exemplary in nature and is not intended to limit the invention or is no intention to be bound by any expressed or implied theory presented in preceding technical filed, background, brief summary or the following description.

The terms and the well known process for the following detailed description are defined as below.

Various steps in manufacturing MOS transistors are well known and so, in the interest of brevity, many conventional steps will only be mentioned briefly herein or will be omitted entirely without providing the well known process details in order to explain concisely.

“semiconductor substrate” may be a bulk silicon wafer or thin layer of silicon on an insulating layer (commonly known as silicon-insulator or SOD that, in turn, is supported by a silicon carrier wafer.

Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

In a typical complementary MOS (CMOS) integrated circuits, P-channel MOS transistors and N-channel MOS transistors each have a relatively wide channel width to provide sufficient drive current. In the present invention, a plurality of MOS transistors is formed on a horizontal plane as well as on a vertical plane formed newly.

The “shallow trench isolation (STI)” is formed to electrically isolate between the N-Well and P-Well and to isolate around individual devices that must be electrically isolated.

A “layer of gate insulator” may be a thermally grown silicon dioxide layer formed by heating the silicon substrate in an oxidizing ambient, or may be a deposited insulator such as a silicon oxide, silicon nitride, a high dielectric constant insulator.

A “deposited insulator” can be deposited by chemical vapor deposition, low pressure chemical vapor deposition (LVCVD), or plasma enhanced chemical vapor deposition (PECVD). A “highly integrated MOS device” in accordance with the present invention can be completed by well known steps such as depositing a layer of dielectric material, etching openings through the dielectric material, forming metallization that extends through the openings.

A highly integrated MOS for one embodiment of the invention will hereinafter be described in detail in conjunction with the drawing figures.

The present invention comprises the horizontal plane formed horizontally and the vertical plane formed vertically on the silicon wafer or on the thin layer of silicon on an insulating layer.

And the present invention has advantages in effective power interconnection and high speed operation, because the length of interconnection for electrical connections between MOS transistors is relatively reduced by highly integrating MOS transistors on three-dimensional spaces, by forming MOS transistors on vertical planes as well as horizontal planes after filling the trench with an insulating materials, thus resistance and parasitic capacitance of interconnection become reduced.

Herein one portion of the horizontal planes and vertical planes is doped with P-type impurity dopants, another portion is doped with N-type impurity dopants, wherein the MOS transistors have a combined source region and drain region, or an individual source region or drain region, and a common gate or individual gates electrodes, or N-channel MOS transistors or P-channel MOS transistors on the horizontal planes and the vertical planes. It is preferable to form N-channel and P-channel transistors on the active regions of the horizontal planes and vertical planes.

Namely, the present invention can increase integration density by doping one portion of the horizontal planes and vertical planes, forming source and drain region, and forming N-channel transistors or P-channel transistor, or N-channel transistors and P-channel transistors on the vertical planes newly formed.

A polycrystalline silicon on the horizontal planes of a semiconductor substrate is patterned by photolithography and etching in order to form gate electrodes of the transistors on the active regions.

It is preferable that the polycrystalline silicon is deposited in order to prepare a gate layer on the vertical planes, after an insulating layer filled reaches the height of a bottom boarder of channel on the vertical planes.

Hereinafter, a method of manufacturing a highly integrated MOS in accordance with one embodiment of the invention will be described in detail in conjunction with the drawing figures.

A method of manufacturing a highly integrated MOS device comprises the steps of: preparing for semiconductor substrate; forming vertical planes and a bottom horizontal plane by etching the semiconductor substrate; forming active regions on the vertical planes and the horizontal planes; forming a layer of gate insulator on the vertical planes and the horizontal planes; patterning a polycrystalline silicon by photolithography and etching to form gate electrodes of N-channel MOS transistors on active regions and electrodes of P-channel MOS transistors on other active regions; forming sidewall spacer of the gate electrode; filling a trench for forming vertical planes with an insulating layer until reaching the height of a bottom boarder of transistor channel on the vertical planes; in turn, depositing a polycrystalline silicon in order to prepare a gate layer on the vertical planes; patterning a polycrystalline silicon by photolithography and etching to form gate electrodes of N-channel MOS transistors on active regions and electrodes of P-channel MOS transistor on other active regions;

One embodiment in accordance with the invention will be described in detail hereafter.

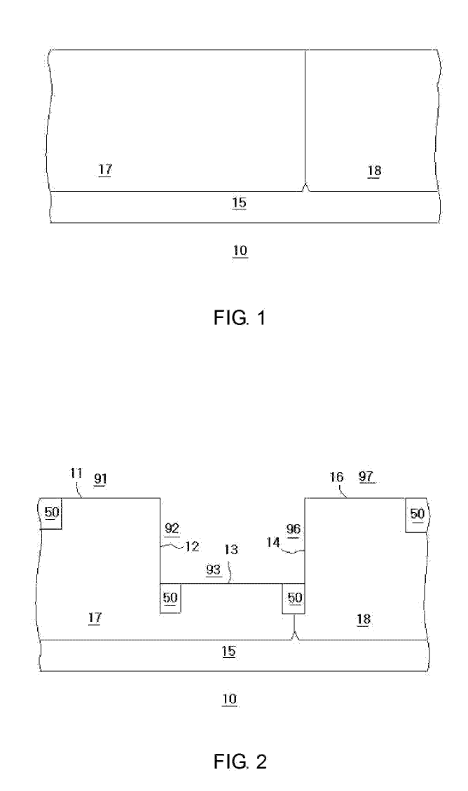

As illustrated in FIG. 1, the fabrication of a highly integrated MOS device 10 in accordance with an embodiment of the invention begins with providing a semiconductor substrate 15.

The semiconductor substrate 15 is preferably monocrystalline silicon that is here illustrated, without limitation as bulk silicon wafer.

It is preferable that one portion 17 of the silicon wafer is doped with P-type impurity dopants (a P-well) and another portion 18 is doped with N-type impurity dopants (an N-well). The P-well and N-well can be doped to the appropriate conductivity, for example, by ion implantation.

Subsequently, four vertical planes and one bottom horizontal plane are formed by deeply etching inward from surface of the semiconductor substrate 15.

The etching can is performed, for example, by plasma etching in Hbr/O₂ or Cl chemistry.

Therefore, four vertical planes formed in accordance with the invention become additional space to form a plurality of MOS transistors.

As illustrated in FIG. 2, for example, left and right vertical planes and a bottom horizontal plane are illustrated as cross-section view.

Front and back vertical planes are not illustrated for description in the present invention because they are formed like left and right planes.

The method of manufacturing a highly integrated MOS device in accordance with the present invention comprises the steps of forming a plurality of MOS transistors on the horizontal plane, as well as forming newly vertical plane in the semiconductor substrate, forming a plurality of MOS transistors on the vertical planes.

The MOS transistors have a combined source region and drain region, or an individual source region and drain region, and have a common gate electrode or an individual gate electrode.

The vertical planes are formed by etching a semiconductor substrate and additionally a plurality of MOS transistors can be formed on the vertical planes as new space to be positioned, therefore integration density can be increased.

Also, it has advantages in effective power interconnections and high speed operation, because the length of interconnection for electrical connections between MOS transistors is relatively reduced by highly integrating MOS transistors on three-dimensional spaces which are created unlike prior art, thus resistance and parasitic capacitance of interconnection become reduced.

As illustrated in FIG. 2, spaces for forming a plurality of N-channel transistors 91, 92, 93 and a plurality of P-channel transistors 96, 97 are illustrated as one portion of a highly integrated MOS device 10 in accordance with the invention.

Although a highly integrated MOS device 10 in accordance with the invention was illustrated as complementary MOS transistors, the invention can be applied to MOS devices comprising only N-channel transistors or only P-channel transistors.

As illustrated in FIG. 2-4, shallow trench isolation (STI) 50 defines active regions 11, 12, 13 to form N-channel MOS transistors 91, 92, 93 and active regions 96, 97 to form P-channel MOS transistors.

Generally, the semiconductor substrate includes the STI. The STI is etched into surface and filled with an insulating material.

The surface is planarized after the STI is filled with the insulating material, for example, is planarized by using chemical mechanical planarization (CMP).

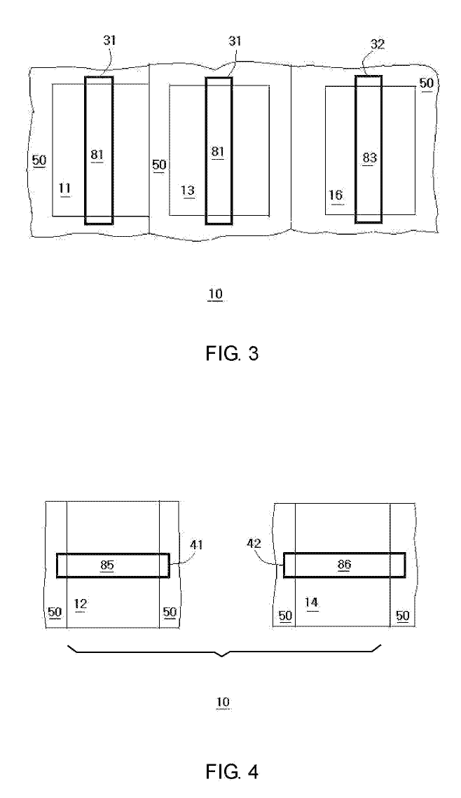

As illustrated in FIG. 3, a bottom horizontal plane provides space to form active region 13.

Also, as illustrated in FIG. 4, left and right vertical planes provide space to form active regions 12, 14.

According to one embodiment of the present invention, N-channel transistors 91, 92, 93 and P-channel transistors 96, 97 are formed on the active regions 11, 13, 16 of the horizontal planes and on the active regions 12, 14 of the vertical planes of the semiconductor substrate 15.

The N-channel transistors 91, 92, 93 and the P-channel transistors 96, 97 comprise each source, drain and gate.

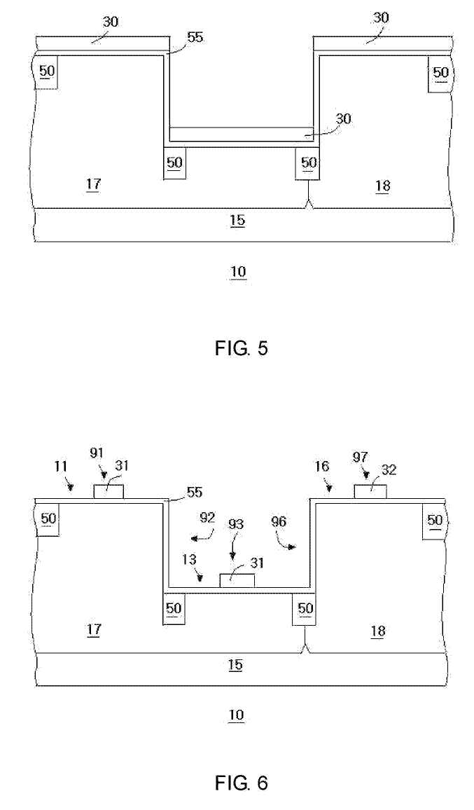

As illustrated in FIG. 5, a layer of gate insulator 55 is formed on the surface of active regions 11, 12, 13, 14, 16 and on the surface of the semiconductor substrate 15.

The layer of insulator corresponds to an insulator deposited equivalently on the STI and on the semiconductor substrate.

Also the gate insulator material 55 is typically 1-10 nanometers (nm) in thickness.

In accordance with one embodiment of the invention, a layer of polycrystalline silicon 30 is deposited onto the layer of gate insulator. The layer of polycrystalline silicon 30 is preferably deposited as undoped polycrystalline silicon and is subsequently impurity doped by ion implantation.

A layer (not illustrated) of hard mask material such as silicon oxide, silicon nitride, or silicon oxynitride can be deposited onto the surface of the polycrystalline silicon 30.

The polycrystalline material can be deposited to a thickness of about 100 nm

by low pressure chemical vapor deposition (LPCVD) by the hydrogen reduction of silane. The hard mask material can be deposited to a thickness of about 50 nm, also by LPCVD.

As illustrated as FIG. 6, the polycrystalline silicon 30 can is patterned by photolithography and etching in order to form a gate electrode 31 of N-channel MOS transistor on active regions 11, 13 of the horizontal planes, and gate electrode 32 of P-channel MOS transistor on active region 16 of the horizontal plane of the semiconductor substrate 15.

The gate electrode 31 is positioned on the channel 81 of N-channel MOS transistors 91, 93 and the gate electrode 32 is positioned on the channel 83 of P-channel MOS transistor 97.

The gate electrodes 31, 32 are illustrated in, also FIG. 3. The polycrystalline silicon can be etched in desired pattern by, for example, plasma etching in Cl or Hbr/O₂ chemistry.

Following gate electrode patterning, the thin layer (not illustrated) of silicon oxide is thermally grown on the opposing sidewall of gate electrodes 31, 32 by heating the polycrystalline silicon in an oxidizing ambient.

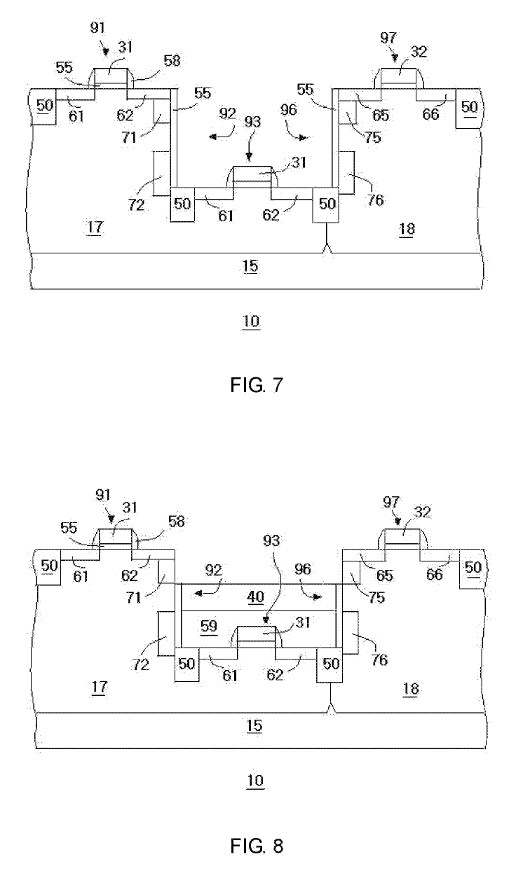

In accordance with one embodiment of the invention, as illustrated in FIG. 7, the sidewall spacers 58 are formed on the opposing sidewalls of gate electrodes 31 and 32, respectively.

Sidewall spacers 58, gate electrodes 31, 32, and STI 50 are used as an implantation mask for source regions 61, 66 and drain regions 62, 65 in spaced apart self alignment with N-channel transistor gate electrodes 31 and

P-channel transistor gate electrodes 32.

N-type conductivity determining ions are implanted to form source regions 61 and drain regions 62 of N-channel transistors 91, 93.

Similarly, P-type conductivity determining ions are implanted to form source region 66 and drain region 65 of P-channel transistor 97.

Subsequently, N-type conductivity determining ions are implanted with different depth to form source region 71 and drain region 72 of N-channel transistor 92 on the left vertical plane.

Similarly, P-type conductivity determining ions are implanted with different depth to form source region 75 and drain region 76 of P-channel transistor 96 on the right vertical plane.

As illustrated in FIG. 8, the layer 59 of an insulating material is deposited

until reaching the height of a bottom boarder of channel 85 of N-channel transistor 92 and channel 86 of P-channel transistor 96, in turn, a polycrystalline silicon 40 is deposited.

The polycrystalline silicon 40 can be deposited to a thickness corresponding to channel length by LPCVD by the hydrogen reduction of silane.

The embodiment of the invention is in case that the width direction of channels 85, 86 is horizontal direction, and the same height each other.

If the height of the channels 85, 86 are different, the gate layer can be formed by depositing and filling the layer of insulating material 59 according to the height, in turn, by depositing the polycrystalline silicon 40, and by repeating this.

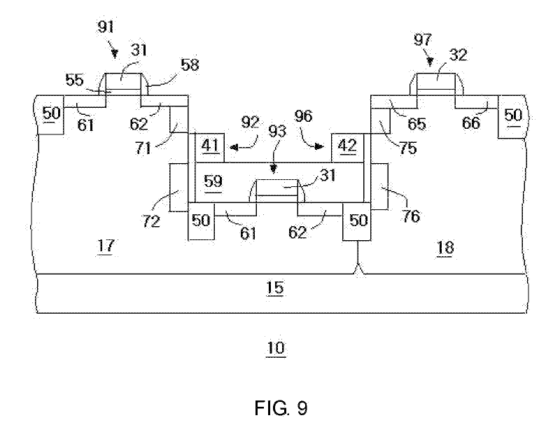

As illustrated in FIG. 9, a gate electrode 41 of N-channel transistor on the active region 12, a gate electrode 42 of P-channel transistor on the active region 14 can be patterned by photolithography and etching as described in the foregoing description.

The gate electrodes 41, 42 are illustrated in also FIG. 4 by solid line.

The highly integrated MOS device in accordance with the invention can be completed by well known steps (not illustrated) such as depositing a layer of dielectric material, etching opening through the dielectric material to expose portions of the source and drain regions, and forming metallization that extends through the openings to electrically contact the source and drain regions. Further layers of interlayer dielectric material, additional layers of interconnect metallization, and the like may also be applied and patterned to achieve the proper circuit function of the integrated circuits being implemented.

While at least one exemplary embodiment has been presented in the foregoing detailed description, it should be appreciated that a vast number of variations exist. It should also be appreciated that the exemplary embodiment or exemplary embodiments are only examples, are not intended to limit the scope, applicability, or configuration of the invention in any way.

What is claimed is:

1. A method of manufacturing a highly integrated MOS device in and on a semiconductor substrate comprising the steps of:
(1) forming a gate insulator layer on a semiconductor substrate;
(2) forming trenches for isolation by etching on a surface of the semiconductor substrate;
(3) planarizing the trenches in the semiconductor substrate after filling the trenches with an insulating material;
(4) forming a plurality of MOS transistors on horizontal planes of the semiconductor substrate;
(5) forming vertical planes and a bottom horizontal plane by etching the semiconductor substrate; and
(6) forming a plurality of MOS transistors on the vertical planes.

2. The method of claim 1, wherein said MOS transistors at the step (4) and the step (6), one portion of the horizontal planes and the vertical planes is doped with P-type impurity dopants, another portion is doped with N-type impurity dopants.

3. The method of claim 1, wherein said MOS transistors at the step (4) and the step (6) comprising:
having a combined source region and drain region, or an individual source region and drain region; and
having a common gate electrode or an individual gate electrode.

4. The method of claim 1, wherein said MOS transistors at the step (4) and the step (6) can be formed as N-channel MOS transistors, or P-channel MOS transistors in the horizontal planes and in the vertical planes.

5. The method of claim 1, wherein said MOS transistors at the step (4) and the step (6) can be formed as N-channel transistor and P-channel transistors in the horizontal planes and in the vertical planes.

6. The method of claim 1, wherein said MOS transistors at the step (4) comprise the step of patterning a polycrystalline silicon by photolithography and etching to form gate electrodes of N-channel MOS transistors on active regions, or gate electrodes of P-channel MOS transistors on other active regions.

7. The method of claim 1, wherein said MOS transistors at the step (6) further comprise the steps of filling a trench for forming vertical planes with an insulating layer until reaching the height of a bottom boarder of transistor channel on the vertical planes, in turn, depositing a polycrystalline silicon in order to prepare a gate layer on the vertical planes.

8. A highly integrated MOS device, comprising:
a horizontal plane formed horizontally in a semiconductor substrate;
a plurality of vertical planes formed vertically in the semiconductor substrate; and
a plurality of MOS transistors on the vertical planes.

9. The highly integrated MOS device of claim 8, further comprising:
at least one portion of the horizontal planes and the vertical planes can include a P-well.

10. The highly integrated MOS device of claim 8, further comprising:
at least one portion of the horizontal planes and the vertical planes can include an N-well.
